(19) United States
(12) Patent Application Publication
(10) Pub. No.: US 2018/0295739 A1
(43) Pub. Date: Oct. 11, 2018

(54) CABINET

(71) Applicant: ZHONGSHAN RIKON ELECTRIC APPLIANCES CO., LTD., Zhongshan (CN)

(72) Inventors: Tao LU, Zhongshan (CN); Hong ZHANG, Zhongshan (CN)

(21) Appl. No.: 16/003,098

(22) Filed: Jun. 7, 2018

Related U.S. Application Data
(63) Continuation of application No. PCT/CN2016/105009, filed on Nov. 8, 2016.

(30) Foreign Application Priority Data
Dec. 8, 2015 (CN) 201510900683.0

(51) Int. Cl. H05K 7/14; A47B 88/40; F25D 29/00

(52) U.S. Cl. CPC H05K 7/1421; A47B 88/40; A47F 3/0478; H05K 7/1427; F25D 29/005

(57) ABSTRACT

The present invention discloses a cabinet including a cabinet body extendable from the cabinet body and is movably connected with the cabinet body through a telescopic structure. The telescopic structure includes a guide rail structure, and the circuit board is movably connected to the cabinet body through the guide rail structure in such a way that the circuit board extends from the cabinet body. In the present invention, by movably connecting, to the cabinet body, a circuit board capable of extending from the cabinet body through a telescopic structure, the examination and maintenance of the circuit board or the connection to the circuit board for debugging, detection or testing can be realized just by pulling the circuit board out, without disassembling the cabinet body. Accordingly, it is convenient for the examination and maintenance of the circuit board or the connection to the circuit board for debugging, detection or testing.

### TECHNICAL FIELD

The present invention relates to a cabinet, and in particular to a cabinet for refrigerators, freezers, cold-storage cabinets, chillers, wine cabinets, storage cabinets or display cabinets.

### BACKGROUND OF THE PRESENT INVENTION

In existing refrigeration facilities or storage facilities such as refrigerators, freezers, cold-storage cabinets, chillers, wine cabinets, storage cabinets or display cabinets, devices such as condensers or compressors and control circuit boards are generally provided. The circuit boards are electrically connected to the condensers, the compressors, switches and the like. The in-cabinet circuit board is generally fixed in a cabinet body. If the circuit board goes wrong, the cabinet body needs to be powered off and then disassembled by a tool for the purpose of examination and maintenance of the circuit board. The debugging, detection and testing can also be realized by disassembling the cabinet body and then connecting an instrument to the circuit board. In the above cases, only after the cabinet body is disassembled, the circuit board can be examined and maintained or the connection to the circuit board can be realized for debugging, detection and testing. As a result, it is very convenient. Moreover, foods in the cabinet body need to be taken out when the cabinet body is disassembled. It is time-consuming, and the refrigeration of the foods is influenced. Additionally, toppling or rolling the cabinet over during the disassembly of the cabinet body will have adverse impact on the condenser and the compressor and will influence the normal operation of the condenser and the compressor.

### SUMMARY OF THE PRESENT INVENTION

An objective of the present invention is to provide a cabinet in which the examination and maintenance of the circuit board or the connection to the circuit board for debugging, detection and testing can be realized conveniently without disassembling the cabinet body, and which is simple in structure and low in cost, in order to overcome the deficiencies of the prior art.

The objective of the present invention is realized by the following technical solution.

A cabinet is provided, including a cabinet body, wherein the cabinet body is movably connected, through a telescopic structure, to a circuit board capable of extending from the cabinet body.

The cabinet is characterized in that the telescopic structure includes a guide rail structure, and the circuit board is movably connected to the cabinet body through the guide rail structure in such a way that the circuit board can extend from the cabinet body.

The cabinet is characterized in that the guide rail structure includes fixed guide rails arranged on the cabinet body, and sliding guide rails matched with the fixed guide rails are provided on the circuit board.

The cabinet is characterized in that the circuit board is mounted within a control box, and the control box is movably connected to the cabinet body through the guide rail structure.

The cabinet is characterized in that both the telescopic structure and the circuit board are arranged in a lower portion of the front of the cabinet body.

The cabinet is characterized in that both the telescopic structure and the circuit board are arranged on a side of the cabinet body.

The cabinet is characterized in that an accommodating space for allowing the control box to extend or retract is provided on the cabinet body, and the fixed guide rails are fixed on two side walls of the accommodating space.

The cabinet is characterized in that the telescopic structure includes clamping edges formed by extending two side edges of a substrate of the circuit board, an accommodating space for accommodating the circuit board is provided on the cabinet body, clamping grooves are formed on two side walls of the accommodating space, and the clamping edges of the circuit board are directly clamped into the clamping grooves to form the pull-type telescopic structure.

The cabinet is characterized in that the telescopic structure includes a bracket on which the circuit board is mounted, and the bracket is movably connected to the cabinet body through an elastic clamping structure.

The cabinet is characterized in that the elastic clamping structure includes a magnet fixed in the cabinet body, and an iron block matched with the magnet is provided on an inner side of the bracket.

The present invention has the following beneficial effects.

In the present invention, by movably connecting, to the cabinet body, a circuit board capable of extending from the cabinet body through a telescopic structure, the examination and maintenance of the circuit board or the connection to the circuit board for debugging, detection or testing can be realized just by pulling the circuit board out, without disassembling the cabinet body. Accordingly, it is convenient for the examination and maintenance of the circuit board or the connection to the circuit board for debugging, detection or testing. Moreover, the present invention is simple in structure and low in cost.

### BRIEF DESCRIPTION OF THE DRAWINGS

FIG. 1 is a stereoscopic diagram of the present invention;

FIG. 2 is a schematic structure diagram of a telescopic structure and a circuit board in the present invention;

FIG. 3 is a structure diagram of FIG. 2 after a control box cover is opened;

FIG. 4 is a structurally exploded view of FIG. 2;

FIG. 5 is a schematic structural diagram of Embodiment 2 of the present invention; and

FIG. 6 is a schematic structural diagram of Embodiment 3 of the present invention.

### DETAILED DESCRIPTION OF THE PRESENT INVENTION

The present invention will be further described below with reference to the accompanying drawings.

### Embodiment 1

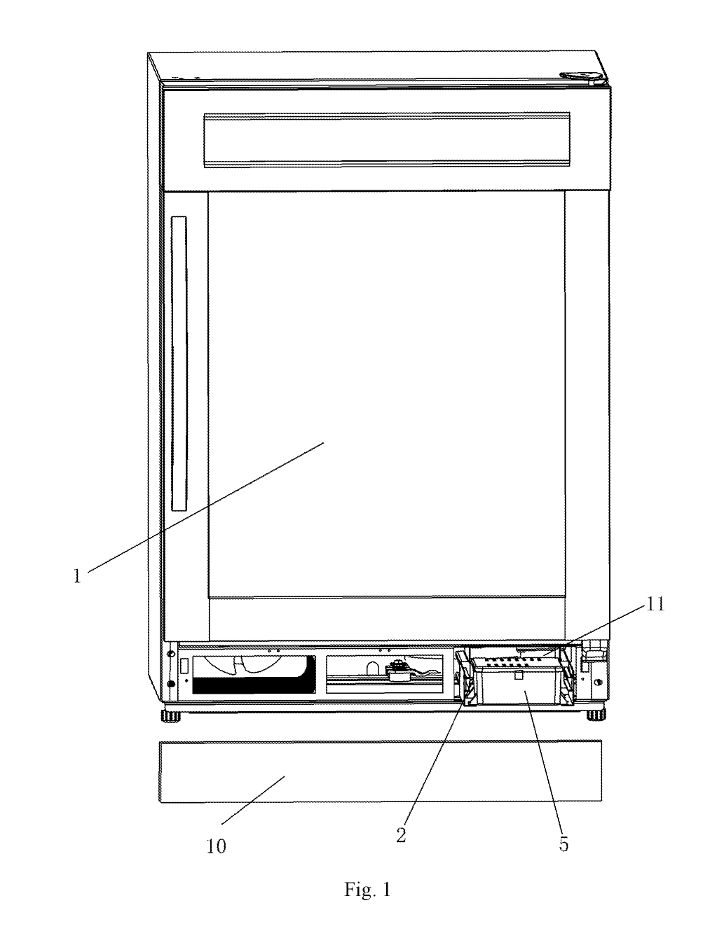

As shown in FIG. 1, the present invention will be described by taking a wine cabinet as an example. A cabinet is provided, including a cabinet body 1. A compressor, a condenser, a fan and other devices are provided within the cabinet body 1. The cabinet body 1 is movably connected, through a telescopic structure 2, to a circuit board 3 capable of extending from the cabinet body. The examination and maintenance of the circuit board or the connection to the circuit board for debugging, detection or testing can be realized just by pulling the circuit board out, without disassembling the cabinet body. Accordingly, it is convenient for the examination and maintenance of the circuit board or the connection to the circuit board for debugging, detection or testing.

In the present invention, the telescopic structure 2 includes a guide rail structure 4, the guide rail structure 4 includes fixed guide rails 41 arranged on the cabinet body, and sliding guide rails 42 matched with the fixed guide rails are provided on the circuit board 3.

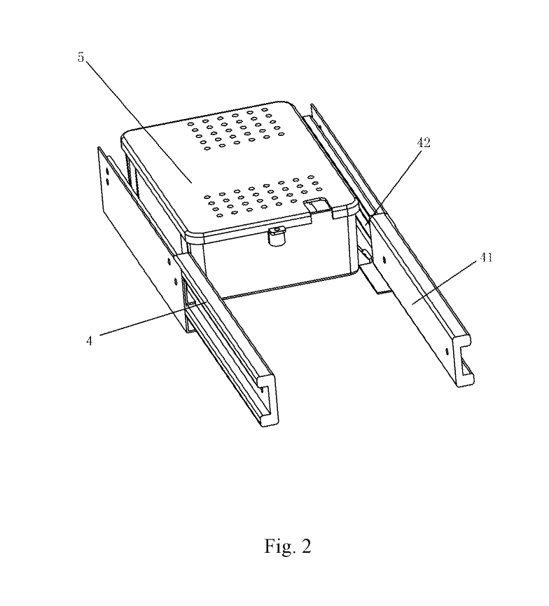

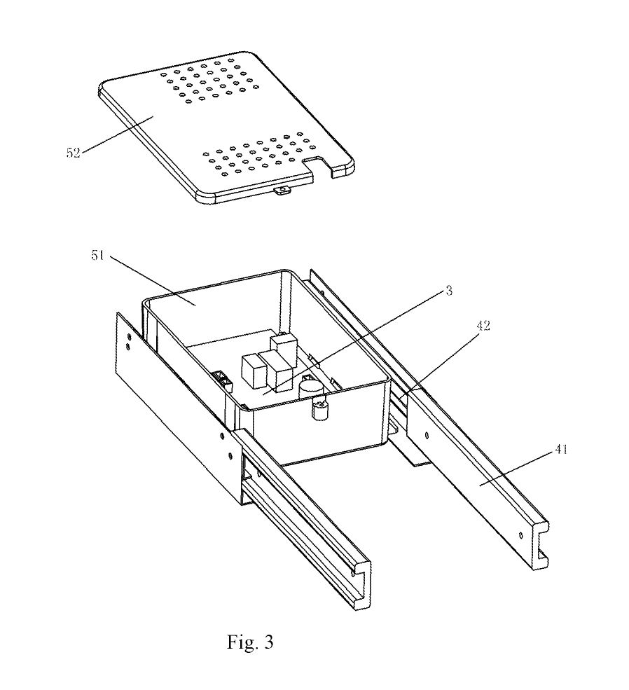

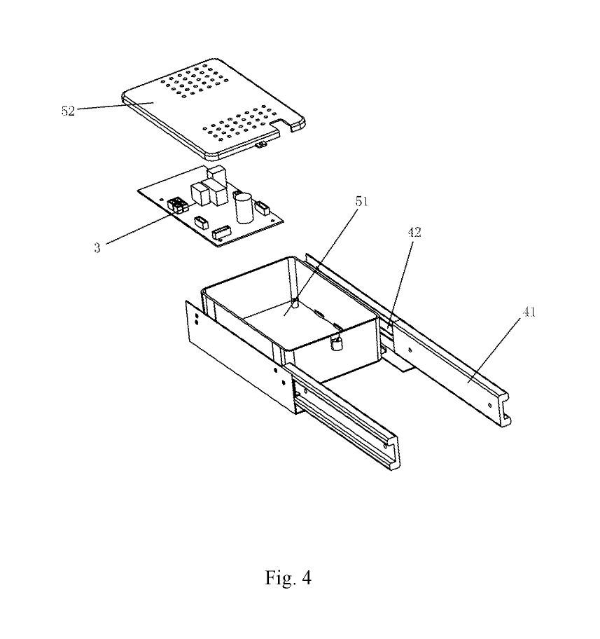

As shown in FIGS. 2, 3 and 4, in the present invention, the circuit board 3 is mounted within a control box 5, and the sliding guide rails 42 matched with the fixed guide rails are mounted on two sides of the control box 5, so that the control box 5 is movably connected to the cabinet body 1 through the guide rail structure 4. The control box 5 includes a box body 51. A box cover 52 is covered on the box body 51, and the sliding guide rails 42 are mounted on two sides of the box body 51 of the control box 5.

In the present invention, both the telescopic structure 2 and the circuit board 3 are arranged in a lower portion of the front of the cabinet body, or in an upper portion of the front of the cabinet body, or on a side of the cabinet body, or in the rear of the cabinet body. In this embodiment, both the telescopic structure 2 and the circuit board 3 are arranged in the lower portion of the front of the cabinet body.

In the present invention, in order to mount the telescopic structure, an accommodating space 11 for allowing the control box to extend or retract is provided on the cabinet body 1. The length of the accommodating space 11 is slightly longer than that of the control box, so that the control box can be completely accommodated within the cabinet body. The fixed guide rails 41 are fixed on two side walls of the accommodating space.

For more beautiful appearance and also for safety, in the present invention, a decorative cover 10 is preferably provided outside the accommodating space 11. The decorative cover 10 can be mounted on the cabinet body through a detachable structure. In this way, it is convenient to assemble and disassemble the decorative cover 10 and pull out the circuit board.

### Embodiment 2

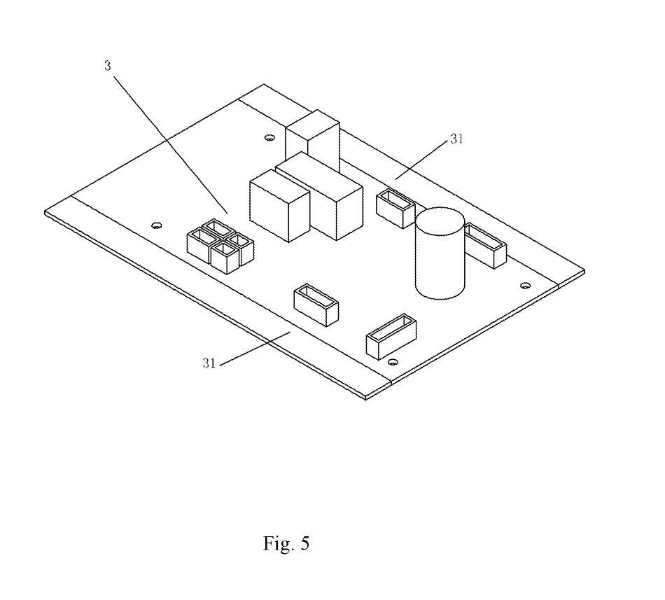

As shown in FIG. 5, in this embodiment, in the telescopic structure 2 of the present invention, two side edges of a substrate of the circuit board 3 can be extended to form clamping edges 31, an accommodating space 11 for accommodating the circuit board is provided on the cabinet body, clamping grooves are formed on two side walls of the accommodating space, and the clamping edges of the circuit board are directly clamped into the clamping grooves to form the pull-type telescopic structure.

### Embodiment 3

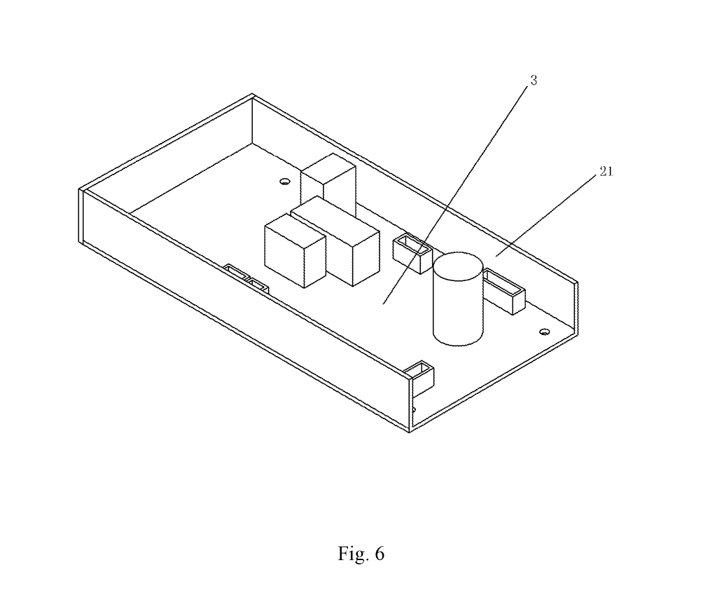

As shown in FIG. 6, in this embodiment, the telescopic structure 2 includes a bracket 21 on which the circuit board is mounted, and the bracket is movably connected to the cabinet body through an elastic clamping structure.

The guide rail structure in this embodiment is the same as the guide rail structure in Embodiment 1.

In this embodiment, the elastic clamping structure includes a magnet fixed in the cabinet body, and an iron block matched with the magnet is provided on an inner side of the bracket.

What is claimed is:

1. A cabinet, comprising a cabinet body (1); wherein a circuit board (3) extendable from the cabinet body (1) is movably connected with the cabinet body (1) through a telescopic structure (2).

2. The cabinet according to claim 1, wherein the telescopic structure (2) comprises a guide rail structure (4), and the circuit board (3) is movably connected to the cabinet body (1) through the guide rail structure (4) in such a way that the circuit board extends from the cabinet body (1).

3. The cabinet according to claim 2, wherein the guide rail structure (4) comprises fixed guide rails (41) arranged on the cabinet body (1), and sliding guide rails (42) matched with the fixed guide rails are provided on the circuit board (3).

4. The cabinet according to claim 2, wherein the circuit board (3) is mounted within a control box (5), and the control box (5) is movably connected to the cabinet body (1) through the guide rail structure (4).

5. The cabinet according to claim 1, wherein the telescopic structure (2) and the circuit board (3) are arranged in a lower portion of the front of the cabinet body (1).

6. The cabinet according to claim 1, wherein the telescopic structure (2) and the circuit board (3) are arranged on a side of the cabinet body.

7. The cabinet according to claim 3, wherein an accommodating space (11) for the expansion and contraction of the control box (1) is provided on the cabinet body (1); and the fixed guide rails (41) are fixed on two side walls of the accommodating space (11).

8. The cabinet according to claim 1, wherein the telescopic structure comprises clamping edges (31) formed by extending two side edges of a substrate of the circuit board (3), an accommodating space (11) for accommodating the circuit board is provided on the cabinet body, clamping grooves are formed on two side walls of the accommodating space, and the clamping edges of the circuit board are directly clamped into the clamping grooves to form a drawing telescopic structure.

9. The cabinet according to claim 1, wherein the telescopic structure comprises a bracket on which the circuit board is mounted; and the bracket is movably connected to the cabinet body through an elastic engagement structure.

10. The cabinet according to claim 9, wherein the elastic engagement structure comprises a magnet fixed in the cabinet body, and an iron block matched with the magnet is arranged on an inner side of the bracket.
